(19) United States
(12) Patent Application Publication
(10) Pub. No.: US 2008/0017852 A1
(43) Pub. Date: Jan. 24, 2008

(54) Conductive Polymer Composition Comprising Organic Ionic Salt and Optoelectronic Device Using the Same

(75) Inventors: Dal Ho Huh, Suwon-si (KR); Mi Young Chae, Yongin-si (KR); Jeong Woo Lee, Bucheon-si (KR)

Correspondence Address: SUMMA, ALLAN & ADDITON, P.A., 11610 NORTH COMMUNITY HOUSE ROAD, SUITE 200, CHARLOTTE, NC, 28277, US

(73) Assignee: CHEIL INDUSTRIES INC., Gumi-si (KR)

(21) Appl. No.: 11/782,025

(22) Filed: Jul. 24, 2007

(30) Foreign Application Priority Data
Jul. 24, 2006 (KR) 2006-0068867

(51) Int. Cl. H01L 51/00; H01B 1/12

(52) U.S. Cl. 257/40; 252/519.34; 257/E51.001

(57) ABSTRACT

Disclosed herein is a conductive polymer composition for an organic optoelectronic device capable of improving efficiency and lifetime. The conductive polymer composition comprises a conductive polymer, at least one organic ionic salt selected from compounds represented by the following Formulae 2 to 5 and a solvent.

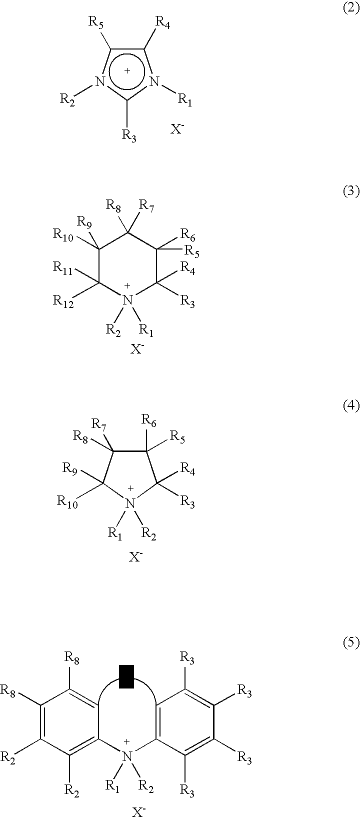

### CROSS REFERENCE TO RELATED APPLICATIONS

This application claims priority from Korean Patent Application No. 2006-0068867 filed Jul. 24, 2006, which is hereby incorporated by reference in its entirety.

### BACKGROUND OF THE INVENTION

1. Field of the Invention

The present invention relates to a conductive polymer composition and an organic optoelectronic device using the same. More specifically, the present invention relates to a conductive polymer composition comprising an organic ionic salt which is capable of improving efficiency and lifetime properties of an organic optoelectronic device, and an organic optoelectronic device using the composition.

2. Description of the Related Art

Optoelectronic devices, e.g., organic light emitting diodes (hereinafter, referred to simply as “OLEDs”), organic solar cells and organic transistors, convert electric energy into light energy, and vice versa.

In particular, with technical developments in the field of flat panel displays (hereinafter, referred to simply as “FPDs”), OLEDs have recently attracted much attention.

Based on rapid technical development, liquid crystal displays (LCDs) have the highest market share (i.e., 80% or more) in the flat panel display products. However, large-screen (e.g., 40 inch or more) LCDs have drawbacks in terms of slow response speed, narrow viewing angle, etc. There is a need for a novel display to overcome these drawbacks.

Under these circumstances, since organic light emitting diodes have advantages of low driving voltage, self-luminescence, slimness, wide viewing angle, rapid response speed, high contrast, and low cost, they have been the focus of intense interest as the only devices capable of satisfying all requirements for next-generation FPDs.

In recent years, a great deal of research has been conducted in the field of optoelectronic devices including OLEDs in order to form a conductive polymer film capable of favorably transporting charges (i.e., holes and electrons) created on electrodes into an optoelectronic device, and thus realizing high efficiency of the device.

When a current is applied to a thin film composed of a fluorescent or phosphorescent organic compound (hereinafter, referred to simply as an “organic film”), electrons are recombinated with holes in the organic film to emit light. OLEDs are self-luminescent devices employing such a phenomenon. To improve luminescence efficiency and lower a driving voltage, OLEDs generally have a multilayer structure including a hole injection layer, a light emission layer and an electron injection layer as organic layers, rather than a monolayer structure exclusively consisting of a light emission layer.

The multilayer structure can be simplified by leaving one multifunctional layer and omitting other layers. OLEDs may have the simplest structure including two electrodes, and a light emission layer interposed between the two electrodes. In this case, the light emission layer is an organic layer capable of performing all functions.

However, for substantial improvement in luminance of OLEDs, an electron injection layer or a hole injection layer must be introduced into a light-emission assembly.

A variety of organic compounds that transport charges (holes or electrons) are disclosed in patent publications. Materials for the organic compounds and use thereof are generally disclosed, for example, in EP Patent Publication No. 387,715, and U.S. Pat. Nos. 4,539,507, 4,720,432, and 4,769,292.

A charge transporting organic compound currently used in organic EL devices is poly(3,4-ethylenedioxythiophene)-poly(4-styrenesulfonate) (PEDOT-PSS) in the form of an aqueous solution, which is commercially available from Bayer AG under the trade name “Baytron-P”.

PEDOT-PSS is widely used in fabrication of OLEDs. For example, PEDOT-PSS is deposited on an electrode made of a material, e.g., indium tin oxide (ITO) by spin coating to form a hole injection layer. PEDOT-PSS is represented by Formula 1 below:

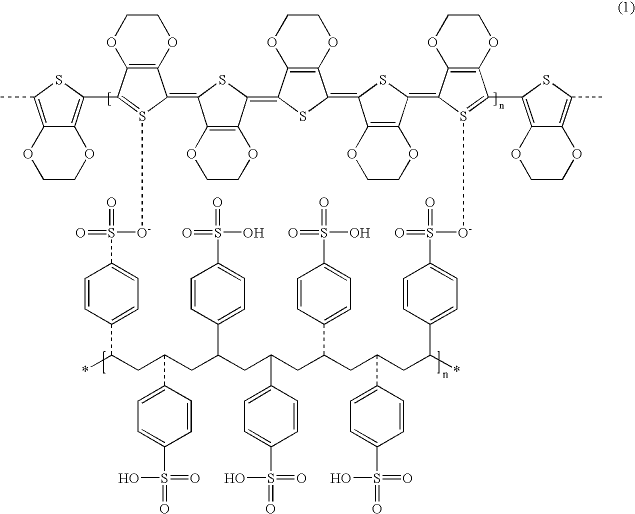

PEDOT-PSS has a structure in which PEDOT is doped with aqueous polyacid as an ionic complex of poly(3,4-ethylenedioxythiophene) (PEDOT) with polyacid of poly(4-styrenesulfonate) (PSS).

In the case where a conductive polymer composition comprising PEDOT-PSS is used to form a hole injection layer, PSS is deteriorated and thus dedoped, or is reacted with electrons and thus decomposed, thereby producing an undesired material such as sulfate. The material may be diffused into adjacent organic films, e.g., a light-emitting layer. The diffusion of the material from the hole injection layer to the light-emitting layer leads to exciton quenching, thus causing deterioration in the efficiency and lifetime of OLEDs.

Accordingly, research continues in an attempt to develop an electrically conductive polymer composition that is capable of solving these problems to improve the efficiency and lifetime of OLEDs.

### SUMMARY OF THE INVENTION

In accordance with one aspect of the present invention, there is provided a conductive polymer composition for an organic optoelectronic device capable of improving efficiency and lifetime. The conductive polymer composition may comprise a conductive polymer, at least one organic ionic salt selected from compounds represented by the following Formulae 2 to 5, and a solvent.

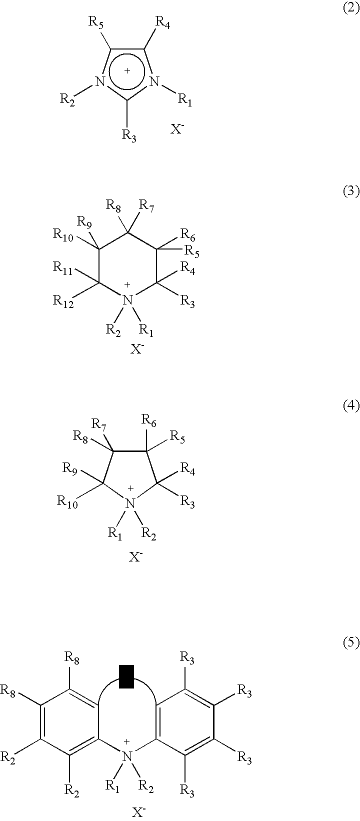

### BRIEF DESCRIPTION OF THE DRAWINGS

The above and other objects, features and other advantages of the present invention will be more clearly understood from the following detailed description taken in conjunction with the accompanying drawings, in which:

FIGS. 1a to 1d are cross-sectional views schematically illustrating a laminate structure of organic light-emitting diodes according to exemplary embodiments of the present invention; and

FIGS. 2 and 3 are graphs illustrating a comparison in the luminescence efficiency between organic light-emitting diodes fabricated in Examples and Comparative Examples.

### DESCRIPTION OF THE PREFERRED EMBODIMENTS

The present invention now will be described more fully hereinafter in the following detailed description of the invention, in which some, but not all embodiments of the invention are described. Indeed, this invention may be embodied in many different forms and should not be construed as limited to the embodiments set forth herein; rather, these embodiments are provided so that this disclosure will satisfy applicable legal requirements.

In one aspect, the present invention is directed to a conductive polymer composition for an organic optoelectronic device comprising: a conductive polymer; at least one organic ionic salt selected from compounds represented by the following Formulae 2 to 5; and a solvent,

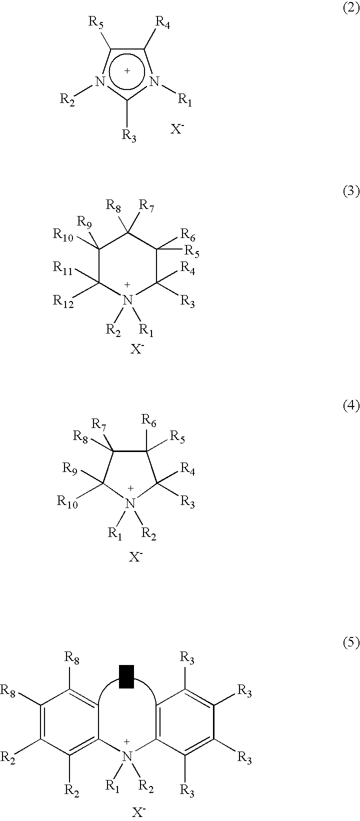

wherein R₁ and R₂ are each independently selected from the group consisting C₁-C₃₀ alkyl groups, C₁-C₃₀ heteroalkyl groups, C₁-C₃₀ alkoxy groups, C₁-C₃₀ heteroalkoxy groups, C₆-C₃₀ aryl groups, C₆-C₃₀ arylalkyl groups, C₆-C₃₀ aryloxy groups, C₂-C₃₀ heteroaryl groups, C₂-C₃₀ heteroarylalkyl groups, C₂-C₃₀ heteroaryloxy groups, C₅-C₃₀ cycloalkyl groups, C₂-C₃₀ heterocycloalkyl groups, C₁-C₃₀ alkylester groups, C₁-C₃₀ heteroalkylester groups, C₆-C₃₀ arylester groups, and C₂-C₃₀ heteroarylester groups; wherein at least one hydrogen bound to carbon of each R₁ and R₂ functional group may be optionally substituted with other functional groups (such as a halogen atom, a hydroxyl group, a nitro group, a cyano group, an amino group (e.g., —NH₂, —NH(R), or —N(R′)(R″), where R′ and R″ are each independently a C₁-C₁₀ alkyl group), an amidino group, a hydrazine group, or a hydrozone group, as discussed below);

R₃ to R₁₂ are each independently selected from the group consisting C₁-C₃₀ alkyl groups, C₁-C₃₀ heteroalkyl groups, C₁-C₃₀ alkoxy groups, C₁-C₃₀ heteroalkoxy groups, C₆-C₃₀ aryl groups, C₆-C₃₀ arylalkyl groups, C₆-C₃₀ aryloxy groups, C₂-C₃₀ heteroaryl groups, C₂-C₃₀ heteroarylalkyl groups, C₂-C₃₀ heteroaryloxy groups, C₅-C₃₀ cycloalkyl groups, C₂-C₃₀ heterocycloalkyl groups, C₁-C₃₀ alkylester groups, C₁-C₃₀ heteroalkylester groups, C₆-C₃₀ arylester groups, and C₂-C₃₀ heteroarylester groups; wherein at least one hydrogen bound to carbon of each R₃ to R₁₂ functional group may be optionally substituted with other functional groups (such as a halogen atom, a hydroxyl group, a nitro group, a cyano group, an amino group (e.g., —NH₂, —NH(R), or —N(R′)(R″), where R′ and R″ are each independently a C₁-C₁₀ alkyl group), an amidino group, a hydrazine group, or a hydrozone group, as discussed below);

X⁻ is an anion group wherein X is any molecule or atom that can be stabilized in an anion state and examples thereof include F, Cl, Br, I, BF₄, PF₆ and (CₙF₂ₙ₊₁SO₂)₂N (n is an integer from 1 to 50), provided that C₁ means one carbon atom and C₃₀ means 30 carbon atoms; and

Y is a NH group or a heteroatom selected from N, O, P and S being bonded to a C₁-C₂₀ alkyl group or a C₆-C₂₀ aryl group.

In another aspect, the present invention is directed to a conductive polymer film that can be prepared by removing entirely or partly the solvent from the conductive polymer composition.

Details of other aspects and exemplary embodiments of the present invention are encompassed in the following detailed description and the accompanying drawings.

The advantages, features and their achieving methods of the present invention will be more clearly understood from the following detailed description taken in conjunction with the accompanying drawings. Those skilled in the art will appreciate that various modifications, additions, and substitutions to the specific examples are possible, without departing from the scope and spirit of the invention as disclosed in the accompanying claims. These examples are given for the purpose of illustration and are not to be construed as limiting the scope of the invention. Throughout the disclosure of the present invention, the same or similar elements are denoted by the same reference numerals.

In the drawings, the size and thickness of layers and regions are exaggerated for clarity of the present invention. It will be understood that when an element such as a layer or film is referred to as being “on” another element, it can be directly on the other element or intervening elements may also be present between the elements.

Specific examples of the substituent “alkyl group” as used herein include linear or branched alkyl groups such as but not limited to methyl, ethyl, propyl, isobutyl, sec-butyl, tert-butyl, pentyl, iso-amyl, hexyl, and the like. At least one hydrogen atom contained in the alkyl group may be optionally substituted with a functional substituent group such as but not limited to a halogen atom, a hydroxyl group, a nitro group, a cyano group, an amino group (e.g., —NH₂, —NH(R), or —N(R′)(R″), where R′ and R″ are each independently a C₁-C₁₀ alkyl group), an amidino group, a hydrazine group, or a hydrozone group. The substituent “heteroalkyl group” as used herein refers to an alkyl group that contains at least one carbon, for example, one to five carbons, substituted with heteroatoms selected from N, O, P and S atoms.

The substituent “aryl group” as used herein refers to a carbocyclic aromatic system including one or more aromatic rings in which the rings may be attached together in a pendent manner or may be fused. Specific examples of the aryl group include aromatic groups, such as but not limited to phenyl, naphthyl, tetrahydronaphthyl, and the like. At least one hydrogen atom contained in the aryl group may be optionally substituted with a functional substituent as the optional functional substituent group as defined with respect to the substituent “alkyl group”.

The substituent “heteroaryl group” as used herein refers to a C₆-C₃₀ cyclic aromatic system consisting of one to three heteroatoms selected from N, O, P and S atoms and the remaining ring carbon atoms in which the rings may be attached together in a pendant manner or may be fused. At least one hydrogen atom included in the heteroaryl group may be optionally substituted with a functional substituent group which is the same as the optional functional substituent group defined with respect to the substituent “alkyl group”.

Specific examples of the alkoxy group include without limitation methoxy, ethoxy, propoxy, isobutyloxy, sec-butyloxy, pentyloxy, iso-amyloxy and hexyloxy. At least one hydrogen atom included in the alkoxy group may be optionally substituted with a functional substituent group which is the same as the optional functional substituent group defined with respect to the substituent “alkyl group”.

The substituent “arylalkyl group” as used herein refers to a substituent in which hydrogen atoms included in the aryl group defined above are partly substituted with lower alkyl groups, such as methyl, ethyl and propyl radicals. Examples of the arylalkyl group include without limitation benzylmethyl and phenylethyl. At least one hydrogen atom included in the arylalkyl group may be optionally substituted with a functional substituent group which is the same as the optional functional substituent group defined with respect to the substituent “alkyl group”.

The substituent “heteroarylalkyl group” as used herein refers to a substituent in which hydrogen atoms included in the heteroaryl group defined above are partly substituted with lower alkyl groups. The heteroaryl group contained in the heteroarylalkyl group is the same as defined above. At least one hydrogen atom included in the heteroarylalkyl group may be optionally substituted with a functional substituent group which is the same as the optional functional substituent group defined with respect to the substituent “alkyl group”.

The substituent “aryloxy group” as used herein represents radical-O-aryl wherein aryl is as defined above. Specific examples of the aryloxy group include without limitation phenoxy, naphthoxy, anthracenyloxy, phenanthrenyloxy, fluorenyloxy, and indenyloxy. At least one hydrogen atom included in the aryloxy group may be optionally substituted with a functional substituent group which is the same as the optionally functional substituent group defined with respect to the substituent “alkyl group”.

The substituent “heteroaryloxy group” as used herein represents radical-O-heteroaryl wherein heteroaryl is as defined above. At least one hydrogen atom included in the heteroaryloxy group may be optionally substituted with a functional substituent group which is the same as the optional functional substituent group defined with respect to the substituent “alkyl group”.

The substituent “cycloalkyl group” as used herein refers to a monovalent monocyclic system having 5 to 30 carbon atoms. At least one hydrogen atom included in the cycloalkyl group may be optionally substituted with a functional substituent group which is the same as the optional substituent group defined with respect to the substituent “alkyl group”.

The substituent “heterocycloalkyl group” as used herein refers to a C₅-C₃₀ monovalent monocyclic system in which one to three heteroatoms selected from N, O, P and S are included, and the remaining ring atoms are carbon. At least one hydrogen atom included in the heterocycloalkyl group may be optionally substituted with a functional substituent group which is the same as the optional functional substituent group defined with respect to the substituent “alkyl group”.

The substituent “amino group” as used herein refers to —NH₂, —NH(R) or —N(R′)(R″) where R′ and R″ are each independently a C₁-C₁₀ alkyl group.

Specific examples of halogen atoms that can be used in the present invention include fluorine, chlorine, bromide, iodine and astatine.

The organic ionic salt contained in the conductive polymer composition of the present invention exists in a liquid, solid, or intermediate state thereof (i.e., liquid/solid hybrid phase), depending on the kind of substituents, the number of carbon atoms, and the size of the anion.

The content of the organic ionic salt in the conductive polymer composition is not particularly limited. However, in a case where a liquid-phase organic ionic salt is used, the organic ionic salt can be added in an amount of about 30% or less by weight. Meanwhile, in a case where a solid-phase organic ionic salt is used, the organic ionic salt can be added in an amount of about 50% or less by weight.

Since the organic ionic salt has a molecular dipole moment, it has high polarity and is soluble in a polar solvent e.g. water, thus being favorably miscible with the composition. Accordingly, in a case where an optoelectronic device is fabricated using the composition, the device can exhibit a long lifetime.

In addition, since the organic ionic salt is substantially soluble in a polar organic solvent, it prevents damage to an adjacent organic layer (i.e. a light-emitting layer formed using a non-polar solvent) upon application to an optoelectronic device, and enables use of any polar organic solvent instead of water in cases where water is unsuitable for use.

The conductive polymer composition of the present invention can be obtained by preparing a conductive polymer solution from a mixture of a conductive polymer and a solvent in a weight ratio of 0.5:99.5 to 10:90, and adding at least one organic ionic salt selected from compounds represented by Formulae 2 to 5 to the solution. Currently, when the organic ionic salt is present in a liquid state at room temperature, it can be added in an amount of about 0.05 to about 30 parts by weight, based on 100 parts by weight of the solution. Meanwhile, when the organic ionic salt is present in a solid state at room temperature, it can be added in an amount of about 0.05 to about 50 parts by weight, based on 100 parts by weight of the solution.

Any conductive polymer can be used in the present invention so long as it is generally used in fabrication of organic optoelectronic devices. The conductive polymer may include a polymer of one or more monomers selected from: polyaniline represented by the following Formula 6 and derivatives thereof; pyrrole or thiophene represented by the following Formula 7 and derivatives thereof; and cyclic compounds represented by the following Formula 8 and derivatives thereof:

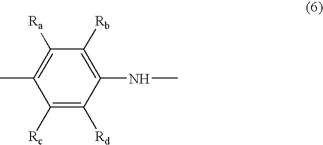

wherein Rₐ, R_{b}, R_{c} and R_{d} are each independently selected from the group consisting of hydrogen, C₁-C₃₀ alkyl groups, C₁-C₃₀ heteroalkyl groups, C₁-C₃₀ alkoxy groups, C₁-C₃₀ heteroalkoxy groups, C₆-C₃₀ aryl groups, C₆-C₃₀ arylalkyl groups, C₆-C₃₀ aryloxy groups, C₆-C₃₀ arylamine groups, C₆-C₃₀ pyrrole groups, C₆-C₃₀ thiophene groups, C₂-C₃₀ heteroaryl groups, C₂-C₃₀ heteroarylalkyl groups, C₂-C₃₀ heteroaryloxy groups, C₅-C₃₀ cycloalkyl groups, C₂-C₃₀ heterocycloalkyl groups, C₁-C₃₀ alkylester groups, C₁-C₃₀ heteroalkylester groups, C₆-C₃₀ arylester groups and C₂-C₃₀ heteroarylester groups; wherein at least one hydrogen bonded to carbon contained in Rₐ, R_{b}, R_{c}, and R_{d} may be optionally substituted with other functional groups (such as defined above with regard to Formulae 2-5)

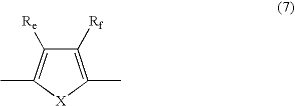

wherein X is a NH group or a heteroatom selected from N, O, P and S being bonded to a C₁-C₂₀ alkyl group or a C₆-C₂₀ aryl group;

Rₑ and R_{f} are each independently selected from the group consisting of a NH group, a heteroatom selected from N, O, P and S being bonded to a C₁-C₂₀ alkyl group or a C₆-C₂₀ aryl group, C₁-C₃₀ alkyl groups, C₆-C₃₀ aryl groups, C₁-C₃₀ alkoxy groups, C₁-C₃₀ heteroalkyl groups, C₁-C₃₀ heteroalkoxy groups, C₆-C₃₀ arylalkyl groups, C₆-C₃₀ aryloxy groups, C₆-C₃₀ arylamine groups, C₆-C₃₀ pyrrole groups, C₆-C₃₀ thiophene groups, C₂-C₃₀ heteroaryl groups, C₂-C₃₀ heteroarylalkyl groups, C₂-C₃₀ heteroaryloxy groups, C₅-C₃₀ cycloalkyl groups, C₂-C₃₀ heterocycloalkyl groups, C₁-C₃₀ alkylester groups, C₁-C₃₀ heteroalkylester groups, C₆-C₃₀ arylester groups and C₂-C₃₀ heteroarylester groups; and wherein at least one hydrogen bonded to carbon contained in Rₑ and R_{f} may be optionally substituted with other functional groups (such as defined above with regard to Formulae 2-5); and

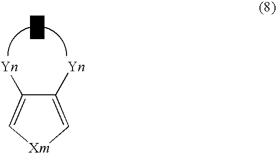

wherein X is a NH group or a heteroatom selected from N, O, P and S being bonded to a C₁-C₂₀ alkyl group or a C₆-C₂₀ aryl group;

Y is a NH group or a heteroatom selected from N, O, P and S being bonded to a C₁-C₂₀ alkyl group or a C₆-C₂₀ aryl group;

m and n are each independently an integer from 0 to 9; and

Z is —(CH₂)ₓ—CR_{g}Rₕ—(CH₂)_{y}, wherein R_{g} and Rₕ are each independently hydrogen, a C₁-C₂₀ alkyl radical or a C₆-C₁₄ aryl radical, or —CH₂—ORᵢ, where Rᵢ is hydrogen, C₁-C₆ alkyl acid, C₁-C₆ alkylester, C₁-C₆ heteroalkyl acid, or C₁-C₆ alkylsulfonic acid; and wherein at least one hydrogen bonded to carbon contained in Z may be optionally substituted with other functional groups (such as defined above with regard to Formulae 2-5) and x and y are each independently an integer from 0 to 5.

Any solvent can be used for the conductive polymer composition of the present invention so long as it can dissolve the conductive polymer. There may be used at least one solvent selected from the group consisting of water, alcohol, dimethylformamide (DMF), dimethylsulfoxide (DMSO), toluene, xylene and chlorobenzene, and the like, and mixtures thereof.

The conductive polymer composition of the present invention may further comprise a crosslinking agent to efficiently improve the crosslinkability of graft conductive copolymers of the conductive polymer. The crosslinking agent can include a physical crosslinking agent and/or a chemical crosslinking agent.

The physical crosslinking agent as used herein refers to a low or high molecular weight compound having at least one hydroxyl (OH) group, which functions to physically crosslink polymer chains without forming any chemical bond.

Specific examples of the physical crosslinking agent include low molecular weight compounds such as glycerol and butanol, and high molecular weight compounds such as polyvinyl alcohol and polyethyleneglycol. In addition, other specific examples of physical crosslinking agents include polyethylenimine and polyvinylpyrolidone.

The content of the physical crosslinking agent in the composition of the present invention can be about 0.001 to about 5 parts by weight, for example, about 0.1 to about 3 parts by weight, based on 100 parts by weight of the conductive polymer composition.

When the physical crosslinking agent is used in an amount within the range as defined above, it efficiently exerts its crosslinkability and renders the thin film morphology of the conductive polymer film to be maintained.

The chemical crosslinking agent refers to a chemical material which chemically crosslinks compounds, induces in-situ polymerization, and forms an interpenetrating polymer network (IPN). As the chemical crosslinking agent, silanes such as tetraethyloxysilane (TEOS) are currently used. In addition, specific examples of the chemical crosslinking agent include polyaziridines, melamine polymers and epoxy polymers.

The content of the chemical crosslinking agent in the composition of the present invention can be about 0.001 to about 50 parts by weight, for example, about 1 to about 10 parts by weight, based on 100 parts by weight of the conductive polymer composition.

When the chemical crosslinking agent is used in an amount within the range as defined above, it efficiently exerts its crosslinkability, and has no great influence on the conductive polymer, thus rendering the conductivity of a conductive polymer thin film to be sufficiently maintained.

To produce a conductive polymer film using the conductive polymer composition as mentioned above, the solvent must be mostly removed from the composition. On the assumption that the overall solvent is removed from the composition, the conductive polymer film can include about 0.05 to about 50 parts by weight of at least one organic ionic salt represented by Formulae 2 to 5, based on 100 parts by weight of the conductive polymer.

In another aspect, the present invention provides a conductive polymer film using the conductive polymer composition and an organic optoelectronic device comprising the film. The optoelectronic device can include organic light-emitting diodes, organic solar cells, and organic transistors and organic memory devices.

Hereinafter, an organic light-emitting diode (OLED), to which the conductive polymer composition of the present invention is applied, will be mentioned in detail.

In the OLED, the conductive polymer composition is used in a charge injection layer (i.e., a hole injection layer or an electron injection layer) to inject holes and electrons into a light-emitting polymer, thereby improving the luminescence intensity and the luminescence efficiency.

In the organic solar cell, the conducting polymer is used for an electrode or an electrode buffer layer to increase quantum efficiency. In the organic transistor, the conducting polymer is used as a material for a gate, source-drain electrode, etc.

The structure of an OLED employing the composition according to the present invention and a method for fabricating the OLED will be described.

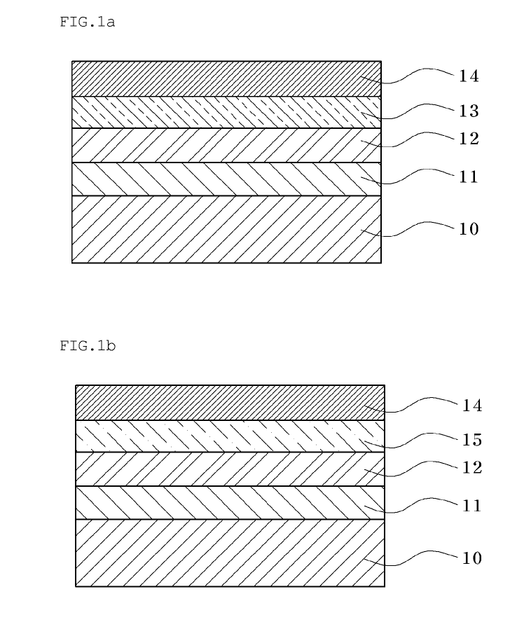

FIGS. 1a to 1d are cross-sectional views schematically illustrating the structure of an OLED according to an exemplary embodiment of the present invention, respectively.

The OLED shown in FIG. 1a comprises a first electrode 10, a hole injection layer (HIL) 11 (also called as a “buffer layer”) made of the conductive composition according to the present invention, a light emitting layer 12, a hole blocking layer (HBL) 13, and a second electrode 14 laminated in this order.

The OLED shown in FIG. 1b has the same laminated structure as that of FIG. 1a, except that an electron transport layer (ETL) 15 instead of the hole blocking layer (HBL) 13 is formed on the light emitting layer 12.

The OLED shown in FIG. 1c has the same laminated structure as that of FIG. 1a, except that a double-layer consisting of a hole blocking layer (HBL) 13 and an electron transport layer (ETL) 15 laminated in this order, instead of the hole blocking layer (HBL) 13 is formed on the light emitting layer 12.

The OLED shown in FIG. 1d has the same structure as that of FIG. 1c, except that a hole transport layer (HTL) 16 is further interposed between the electron transport layer (HIL) 11 and the light-emitting layer 12. The HTL 16 prevents penetration of impurities from the HIL 11 to the light-emitting layer 12.

The OLEDs having the laminate structure as illustrated in FIGS. 1a to 1d, respectively, can be fabricated by a general method.

A more detailed explanation of the general method for fabricating an OLED will be given below.

First, a patterned first electrode 10 is formed on a substrate (not shown). The substrate used in the OLED of the present invention may be a substrate commonly used in the art. Examples include a glass or transparent plastic substrate in view of its high transparency, superior surface smoothness, ease of handling and excellent waterproofing. The thickness of the substrate can be about 0.3 to about 1.1 mm.

Materials for the first electrode 10 are not particularly limited. In a case where the first electrode 10 functions as an anode, the first electrode 10 is composed of an electrically conductive metal or its oxide through which holes are easily injected and specific examples thereof include without limitation indium tin oxide (ITO), indium zinc oxide (IZO), nickel (Ni), platinum (Pt), gold (Au), and iridium (Ir).

The substrate, on which the first electrode 10 is formed, is washed and then is subjected to UV-ozone treatment. The washing is carried out using an organic solvent such as isopropanol (IPA) or acetone.

A hole injection layer (HIL) 11 including the composition of the present invention is formed on the first electrode 10 of the washed substrate. The formation of HIL 11 reduces the contact resistance between the first electrode 10 and the light-emitting layer 12 and improves the hole transporting performance of the first electrode 10 to the light emitting layer 12, thereby improving the driving voltage and the lifetime of the OLED.

The HIL 11 is formed by spin coating the composition, which is prepared by dissolving the conductive polymer of the present invention in a solvent, on the first electrode 10, followed by drying.

The thickness of the HIL 11 may be about 5 to about 200 nm, for example, about 20 to about 100 nm. When the thickness of the HIL 11 is within this range, injection of holes is fully performed and light transmittance is sufficiently maintained. A light-emitting layer 12 is formed on the HIL 11. Specific examples of materials for the light-emitting layer 12 include, but are not necessarily limited to: materials for blue light emission selected from oxadiazole dimer dyes (Bis-DAPOXP), spiro compounds (Spiro-DPVBi, Spiro-6P), triarylamine compounds, bis(styryl)amine (DPVBi, DSA), FIrpic, CzTT, anthracene, TPB, PPCP, DST, TPA, OXD-4, BBOT, and AZM-Zn; materials for blue light emission selected from Coumarin 6, C545T, quinacridone and Ir(ppy)₃; and materials for red light emission selected from and DCM1, DCM2, Eu(thenoyltrifluoroacetone)₃ (Eu(TTA)₃), and butyl-6-(1,1,7,7-tetramethyljulolidyl-9-enyl)-4H-pyran (DCJTB). In addition, examples of suitable light-emission polymers include, but are not limited to phenylene, phenylene vinylene, thiophene, fluorene, spirofluorene, and nitrogen-containing aromatic polymers.

The thickness of the light-emitting layer 12 may be about 10 to about 500 nm, for example about 50 to about 120 nm. When the thickness of the emitting layer is within this range, an increase in leakage current and driving voltage are adjusted to a desired level, and thus the lifetime of the OLED is efficiently maintained.

If necessary, the composition for the light-emitting layer may further comprise a dopant. The content of the dopant varies depending upon a material for the light-emitting layer, but may be generally about 30 to about 80 parts by weight, based on 100 parts by weight of a material for the light-emitting layer (total weight of the host and the dopant). When the content of the dopant is within this range, the luminescence properties of an OLED are efficiently maintained. Specific examples of the dopant include without limitation arylamines, perylenes, pyrroles, hydrazones, carbazoles, stylbenes, starbursts and oxadiazoles, and the like.

The hole transport layer (HTL) 16 may be optionally formed between the HIL 11 and the light-emitting layer 12.

Any material for HTL may be used without particular limitation so long as it functions to transport holes, and for example, the HTL material may include at least one selected from the group consisting of carbazole and/or arylamine-containing compounds, phthalocyanine-based compounds and triphenylene derivatives. More specifically, the HTL may be composed of at least one material selected from the group consisting of 1,3,5-tricarbazolylbenzene, 4,4′-biscarbazolylbiphenyl, polyvinylcarbazole, m-biscarbazolylphenyl, 4,4′-biscarbazolyl-2,2′-dimethylbiphenyl, 4,4′,4″-tri(N-carbazolyl)triphenylamine, 1,3,5-tri(2-carbazolylphenyl)benzene, 1,3,5-tris(2-carbazolyl-5-methoxyphenyl)benzene, bis(4-carbazolylphenyl)silane, N,N′-bis(3-methylphenyl)-N,N′-diphenyl-[1,1-biphenyl]-4,4′-diamine (TPD), N,N′-di(naphthalene-2-yl)-N,N′-diphenyl benzidine (α-NPD), N,N′-diphenyl-N,N′-bis(1-naphthyl)-(1,1′-biphenyl)-4,4′-diamine (NPB), IDE320 (available from Idemitsu), poly(9,9-dioctylfluorene-co-N-(4-butylphenyl)diphenylamine (TFB), and poly(9,9-dioctylfluorene-co-bis-N,N-phenyl-1,4-phenylenediamine) (PFB), but are not limited thereto.

The thickness of the HTL 16 may be about 1 to about 100 nm, for example about 5 to about 50 nm. When the thickness of the HTL 16 is within this range, hole transporting capability is sufficiently maintained and the driving voltage is adjusted to a desired level.

A hole blocking layer (HBL) 13 and/or an electron transport layer (ETL) 15 are formed on the light-emitting layer 12 by deposition or spin coating. The HBL 13 prevents migration of excitons from the light emitting material to the ETL 15 or migration of holes to the ETL 15.

Examples of materials for the hole blocking layer (HBL) 13 may include without limitation phenanthroline-based compounds (e.g., BCP® available from UDC Co., Ltd.), imidazole-based compounds, triazole-based compounds, oxadiazole-based compounds (e.g., PBD®), and aluminium complexes (available from UDC Co., Ltd.).

Examples of materials for the electron transport layer (ETL) 15 may include without limitation oxazoles, isoxazoles, triazoles, isothiazoles, oxadiazoles, thiadiazoles, perylenes, aluminium complexes (e.g., Alq₃ (tris(8-quinolinolato)-aluminium), BAlq, SAlq, and Almq₃, respectively), and gallium complexes (e.g., Gaq′20Piv, Gaq′20Ac, and 2(Gaq′2)).

The thickness of the HBL 13 may be about 5 to about 100 nm, and the thickness of the ELT 15 may be about 5 to about 100 nm. When the thicknesses of the HBL 13 and ELT 15 are within these ranges, electron transporting performance and hole blocking performance are efficiently maintained.

Then, a second electrode 14 is formed on the laminated structure, followed by sealing, to fabricate an OLED.

Materials for the second electrode 14 are not particularly restricted, and examples thereof include low-work function metals, i.e. Li, Cs, Ba, Ca, Ca/Al, LiF/Ca, LiF/Al, BaF₂/Ca, Mg, Ag, Al, and alloys and multilayers thereof. The thickness of the second electrode 14 may be about 50 to about 3,000 Å.

Hereinafter, the fact that the conductive polymer composition according to exemplary embodiments of the present invention contributes to improvement in efficiency properties of an OLED will be demonstrated from specific description with reference to the following Examples. Although not specifically mentioned herein, it will be apparent to those skilled in the art that detailed contents can be derived from the following description.

### 1. EXAMPLES

### (1) Synthesis of Organic Ionic Salt

5 g of N-methylimidazole is dissolved in 250 mL of acetonitryl. 7.2 g of ethylbromide is added dropwise to the solution. The mixture is allowed to react at 80° C. The resulting salt is recrystallized and dried. The salt is dissolved in acetone and 7 g of sodium tetrafluoroborate is then added thereto. The mixture is allowed to react for 24 hours. The unreacted materials are filtered off. The residue is purified through silica and concentrated about 13 g of ethylmethylimidazolium tetrafluoroborate.

### (2) Synthesis of Organic Ionic Salt

5 g of N-methylimidazole is dissolved in 250 mL of acetonitryl. 8 g of butylbromide is added dropwise to the solution. The mixture is allowed to react at 80° C. The resulting salt is recrystallized and dried. The salt is dissolved in acetone and 7 g of sodium tetrafluoroborate is then added thereto. The mixture is allowed to react for 24 hours. The unreacted materials are filtered off. The residue is purified through silica and concentrated to yield about 14 g of butylmethylimidazolium tetrafluoroborate.

### (3) Synthesis of Organic Ionic Salt

5 g of N-methylpiperidine is dissolved in 250 mL of acetonitryl. 8 g of butylbromide is added dropwise to the solution. The mixture is allowed to react at 80° C. The resulting salt is recrystallized and dried. The salt is dissolved in acetone and 7 g of sodium tetrafluoroborate is then added thereto. The mixture is allowed to react for 24 hours. The unreacted materials are filtered off. The residue is purified through silica and concentrated to yield about 14 g of butylmethylpiperidinium tetrafluoro-borate.

### (4) Synthesis of Organic Ionic Salt

5 g of N-methylimidazole is dissolved in 250 mL of acetonitryl. 7.2 g of ethylbromide is added dropwise to the solution. The mixture is allowed to react at 80° C. The resulting salt is recrystallized and dried. The salt is dissolved in acetone and 12 g of LiN(SO₂CF₃)₂ is then added thereto. The mixture is allowed to react for 24 hours. The unreacted materials are filtered off. The residue is purified through silica and concentrated to yield about 15 g of ethylmethylimidazolium bis(perfluoromethylsulfonyl).

### (5) Synthesis of Organic Ionic Salt

5 g of 3-methylpyridine is dissolved in 250 mL of acetonitryl. 8 g of iso-butylbromide is added dropwise to the solution. The mixture is allowed to react at 80° C. The resulting salt is recrystallized and dried. The salt is dissolved in acetone and 12 g of LiN(SO₂CF₃)₂ is then added thereto. The mixture is allowed to react for 24 hours. The unreacted materials are filtered off. The residue is purified through silica and concentrated to yield about 15 g of ethylmethylimidazolium bis(per-fluoro-methyl-sulfonyl)imide.

### (6) Synthesis of Organic Ionic Salt

5 g of N-methylpyrrolidine is dissolved in 250 mL of acetonitryl. 8 g of butylbromide is added dropwise to the solution. The mixture is allowed to react at 80° C. The resulting salt is recrystallized and dried. The salt is dissolved in acetone and 7 g of sodium tetrafluoroborate is then added thereto. The mixture is allowed to react for 24 hours. The unreacted materials are filtered off. The residue is purified through silica and concentrated to yield about 13 g of butylmethylimidazolium tetrafluoroborate.

### (7) Preparation of Conductive Polymer Composition from Organic Ionic Salt

PEDOT/PSS (available from Sigma-Aldrich Corp.) is prepared as a water-soluble conductive polymer from polystyrene sulfonic acid and 3,4-ethylenedioxythiophene in accordance with the preparation method disclosed in U.S. Pat. No. 5,035,926. The PEDOT/PSS is dissolved in water to prepare a PEDOT/PSS solution (ca. concentration: 1.5 wt %) and 1 wt % of an organic ionic salt (not limited to those synthesized in Sections (1) to (6)) is added to the solution, with respect to the weight of the PEDOT/PSS to prepare a conductive polymer composition comprising an organic ionic salt.

### (8) Fabrication of Organic Light-Emitting Diode

An ITO-deposited glass substrate (Corning, 15 Ψ/cm², 1,200 Å) is cut to a size 50 mm×50 mm×0.7 mm. The substrate is sequentially dipped in isopropyl alcohol and pure water, and subjected to ultrasonic cleaning for each about 5 minutes, followed by UV-ozone cleaning for 30 minutes.

A hole injection layer is formed to a thickness of 40 nm on the substrate by spin-coating conductive polymer compositions in which the organic ionic salt prepared in section (4) is dissolved in a concentration of 1 wt % and 3 wt %.

A light-emitting layer is formed to a thickness of 45 nm on the hole injection layer by depositing a green light-emitting polymer (available from Dow chemical Co., Ltd.). A second electrode is formed to a thickness of 100 nm on the light-emitting layer by depositing aluminum (Al) to fabricate OLEDs. These OLEDs thus fabricated will be referred to as Examples 1 and 2.

### (9) Fabrication of Organic Light-Emitting Diode

OLEDs are fabricated in the same manner as in Section (8), except that conductive polymer compositions comprising 1 wt % and 3 wt % of the organic ionic salt prepared in Section (5) are used as materials for the hole injecting layer. These OLEDs thus fabricated will be referred to as Examples 3 and 4.

### (10) Fabrication of Organic Light-Emitting Diode

An OLED is fabricated in the same manner as in Section (8), except that a conductive polymer composition comprising 3 wt % of the organic ionic salt prepared in (6) is used as a material for the hole injecting layer. The OLED thus fabricated will be referred to as an Example 5.

### (11) Fabrication of Organic Light-Emitting Diode

An OLED is fabricated in the same manner as in section (8), except that an aqueous solution of PEDOT/PSS (Batron P 4083® available from Bayer AG) is used as a material for a hole injection layer. The OLED thus fabricated is referred to as a “Comparative Example 1”.

### 2. Evaluation of Luminescence Efficiency

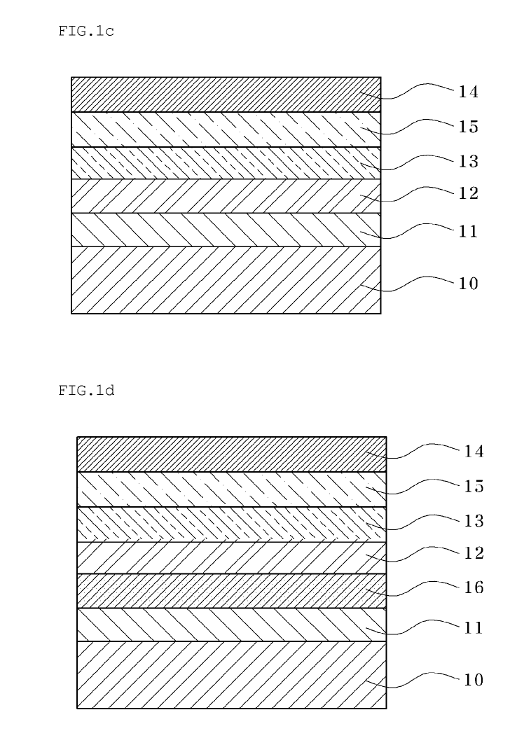

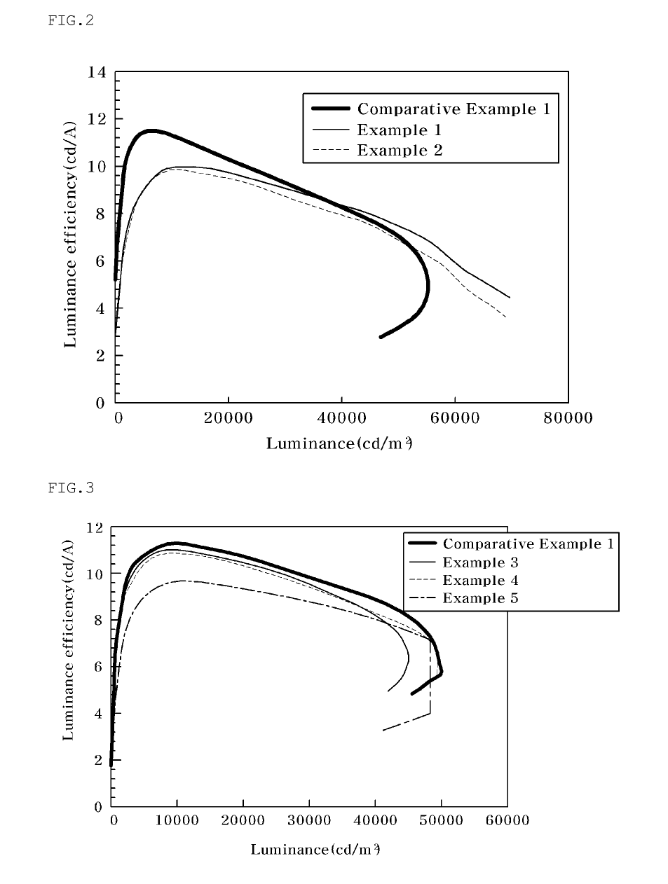

FIGS. 2 and 3 are graphs showing measurement results of luminescence efficiency prepared in Examples 1 to 5 and Comparative Example 1. The measurement of the luminescence efficiency is carried out using a SpectraScan PR650 spectroradiometer. It can be confirmed from the graphs that OELDs fabricated using the conductive polymer composition of the present invention exhibit an about 10% increase in luminescence efficiency and superior high-voltage stability, as compared to that of Comparative Example 1.

As apparent from the foregoing, the conductive polymer composition for an organic optoelectronic device according to the present invention has at least one advantage as follows:

First, the conductive polymer composition contains a very small amount of moieties which are reacted with electrons and thus decomposed.

Second, the conductive polymer composition maintains stable morphology associated with films adjacent to the produced conductive polymer composition film and causes no problem such as exciton quenching.

Third, since the conductive polymer composition has a structure in which a polyacid is chemically bound to a conductive polymer, an organic optoelectronic device, to which the composition is applied, exhibits superior thermal stability and occurs no dedoping phenomenon upon driving.

Fourth, the conductive polymer composition realizes fabrication of an optoelectronic device with superior luminescence efficiency and prolonged lifetime.

Although the preferred embodiments has been described herein in detail with reference to the accompanying drawings, those skilled in the art will appreciate that these embodiments do not serve to limit the invention and that various changes and modifications may be made thereto without departing from the spirit and scope of the invention as defined in the appended claims. Therefore, these embodiments are given for the purpose of illustration and are not to be construed as limiting the scope of the invention.

What is claimed is:

1. A conductive polymer composition for an organic optoelectronic device comprising:
a conductive polymer;
at least one organic ionic salt selected from compounds represented by the following Formulae 2 to 5; and
a solvent, 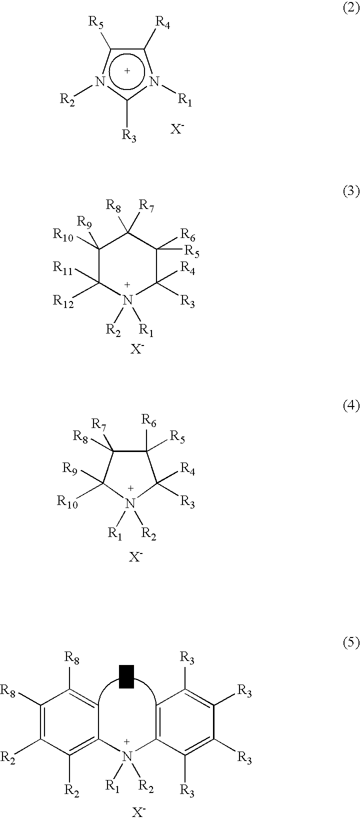
wherein R₁ and R₂ are each independently selected from the group consisting C₁-C₃₀ alkyl groups, C₁-C₃₀ heteroalkyl groups, C₁-C₃₀ alkoxy groups, C₁-C₃₀ heteroalkoxy groups, C₆-C₃₀ aryl groups, C₆-C₃₀ arylalkyl groups, C₆-C₃₀ aryloxy groups, C₂-C₃₀ heteroaryl groups, C₂-C₃₀ heteroarylalkyl groups, C₂-C₃₀ heteroaryloxy groups, C₅-C₃₀ cycloalkyl groups, C₂-C₃₀ heterocycloalkyl groups, C₁-C₃₀ alkylester groups, C₁-C₃₀ heteroalkylester groups, C₆-C₃₀ arylester groups, and C₂-C₃₀ heteroarylester groups, wherein at least one hydrogen bound to carbon of each R₁ and R₂ functional group is optionally substituted with another functional group;
R₃ to R₁₂ are each independently selected from the group consisting C₁-C₃₀ alkyl groups, C₁-C₃₀ heteroalkyl groups, C₁-C₃₀ alkoxy groups, C₁-C₃₀ heteroalkoxy groups, C₆-C₃₀ aryl groups, C₆-C₃₀ arylalkyl groups, C₆-C₃₀ aryloxy groups, C₂-C₃₀ heteroaryl groups, C₂-C₃₀ heteroarylalkyl groups, C₂-C₃₀ heteroaryloxy groups, C₅-C₃₀ cycloalkyl groups, C₂-C₃₀ heterocycloalkyl groups, C₁-C₃₀ alkylester groups, C₁-C₃₀ heteroalkylester groups, C₆-C₃₀ arylester groups, and C₂-C₃₀ heteroarylester groups, wherein at least one hydrogen bound to carbon of each R₃ to R₁₂ functional group is optionally substituted with another functional group;
X⁻ is an anion group wherein X is a molecule or atom that can be stabilized in an anion state and X is selected from F, Cl, Br, I, BF₄, PF₆ and (CₙF₂ₙ₊₁SO₂)₂N, wherein n is an integer from 1 to 50; and
Y is a NH group or a heteroatom selected from N, O, P and S being bonded to a C₁-C₂₀ alkyl group or a C₆-C₂₀ aryl group.

2. The conductive polymer composition according to claim 1, comprising the organic ionic salt in an amount of about 0.05 to about 30 parts by weight, based on 100 parts by weight of the conductive polymer and the solvent.

3. The conductive polymer composition according to claim 1, comprising the organic ionic salt in an amount of about 0.05 to about 50 parts by weight, based on 100 parts by weight of the conductive polymer and the solvent.

4. The conductive polymer composition according to claim 1, wherein the conductive polymer comprises a polymer comprising one or more monomers selected from the group consisting of polyaniline represented by the following Formula 6 and derivatives thereof; and pyrrole or thiophene represented by the following Formula 7 and derivatives thereof, 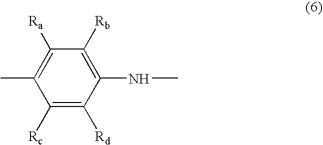
wherein Rₐ, R_{b}, R_{c} and R_{d} are each independently selected from the group consisting of hydrogen, C₁-C₃₀ alkyl groups, C₁-C₃₀ heteroalkyl groups, C₁-C₃₀ alkoxy groups, C₁-C₃₀ heteroalkoxy groups, C₆-C₃₀ aryl groups, C₆-C₃₀ arylalkyl groups, C₆-C₃₀ aryloxy groups, C₆-C₃₀ arylamine groups, C₆-C₃₀ pyrrole groups, C₆-C₃₀ thiophene groups, C₂-C₃₀ heteroaryl groups, C₂-C₃₀ heteroarylalkyl groups, C₂-C₃₀ heteroaryloxy groups, C₅-C₃₀ cycloalkyl groups, C₂-C₃₀ heterocycloalkyl groups, C₁-C₃₀ alkylester groups, C₁-C₃₀ heteroalkylester groups, C₆-C₃₀ arylester groups and C₂-C₃₀ heteroarylester groups, wherein at least one hydrogen bonded to carbon contained in Rₐ, R_{b}, R_{c} and R_{d} is optionally substituted with another functional group; 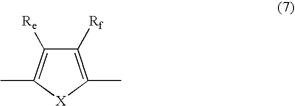
wherein X is a NH group or a heteroatom selected from N, O, P and S being bonded to a C₁-C₂₀ alkyl group or a C₆-C₂₀ aryl group;
Rₑ and R_{f} are each independently selected from the group consisting of a NH group, a heteroatom selected from N, O, P and S being bonded to a C₁-C₂₀ alkyl group or a C₆-C₂₀ aryl group, C₁-C₃₀ alkyl groups, C₆-C₃₀ aryl groups, C₁-C₃₀ alkoxy groups, C₁-C₃₀ heteroalkyl groups, C₁-C₃₀ heteroalkoxy groups, C₆-C₃₀ arylalkyl groups, C₆-C₃₀ aryloxy groups, C₆-C₃₀ arylamine groups, C₆-C₃₀ pyrrole groups, C₆-C₃₀ thiophene groups, C₂-C₃₀ heteroaryl groups, C₂-C₃₀ heteroarylalkyl groups, C₂-C₃₀ heteroaryloxy groups, C₅-C₃₀ cycloalkyl groups, C₂-C₃₀ heterocycloalkyl groups, C₁-C₃₀ alkylester groups, C₁-C₃₀ heteroalkylester groups, C₆-C₃₀ arylester groups and C₂-C₃₀ heteroarylester groups, wherein at least one hydrogen bonded to carbon contained in Rₑ and R_{f} is optionally substituted with another functional group.

5. The conductive polymer composition according to claim 1, wherein the conductive polymer comprises a polymer comprising cyclic compound monomers represented by the following Formula 8 and derivatives thereof: 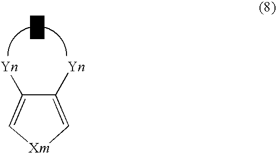
wherein X is a NH group or a heteroatom selected from N, O, P and S being bonded to a C₁-C₂₀ alkyl group or a C₆-C₂₀ aryl group;
Y is a NH group or a heteroatom selected from N, O, P and S being bonded to a C₁-C₂₀ alkyl group or a C₆-C₂₀ aryl group;
m and n are independently an integer from 0 to 9; and
Z is —(CH₂)ₓ—CR_{g}Rₕ—(CH₂)_{y}, wherein R_{g} and Rₕ are each independently hydrogen, a C₁-C₂₀ alkyl radical or a C₆-C₁₄ aryl radical, or —CH₂—ORᵢ, where Rᵢ is hydrogen, C₁-C₆ alkyl acid, C₁-C₆ alkylester, C₁-C₆ heteroalkyl acid, or C₁-C₆ alkylsulfonic acid, wherein at least one hydrogen bonded to carbon contained in Z is optionally substituted with another functional group and wherein x and y are each independently an integer from 0 to 5.

6. The conductive polymer composition according to claim 1, wherein the solvent comprises at least one solvent selected from the group consisting of water, alcohol, dimethylformamide (DMF), dimethylsulfoxide (DMSO), toluene, xylene and chlorobenzene.

7. The conductive polymer composition according to claim 1, further comprising a physical crosslinking agent or a chemical crosslinking agent.

8. The conductive polymer composition according to claim 7, wherein the physical crosslinking agent comprises at least one physical crosslinking agent selected from the group consisting of glycerol, butanol, polyvinyl alcohol, polyethyleneglycol, polyethylenimine and polyvinylpyrolidone.

9. The conductive polymer composition according to claim 7, wherein the chemical crosslinking agent comprises at least one chemical crosslinking agent selected from the group consisting of tetraethyloxysilane (TEOS), polyaziridine, melamine polymers and epoxy polymers.

10. The conductive polymer composition according to claim 7, comprising the physical crosslinking agent in an amount of about 0.001 to about 5 parts by weight, based on 100 parts by weight of the conductive polymer composition.

11. The conductive polymer composition according to claim 7, comprising the chemical crosslinking agent in an amount of about 0.001 to about 50 parts by weight, based on 100 parts by weight of the conductive polymer composition.

12. A conductive polymer composition film for an organic optoelectronic device comprising:
a conductive polymer; and
at least one organic ionic salt selected from compounds represented by the following Formulae 2 to 5; 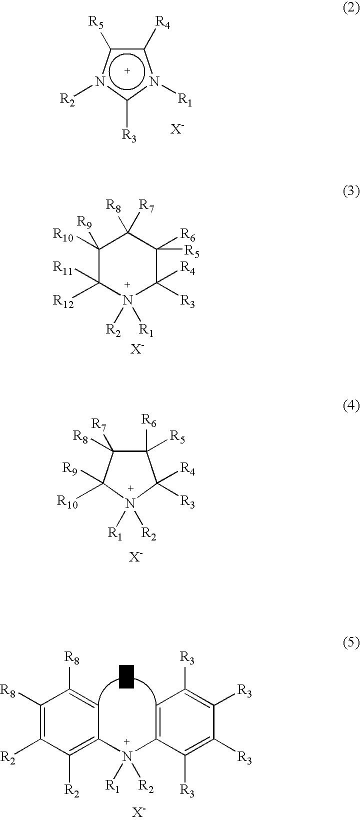
wherein R₁ and R₂ are each independently selected from the group consisting C₁-C₃₀ alkyl groups, C₁-C₃₀ heteroalkyl groups, C₁-C₃₀ alkoxy groups, C₁-C₃₀ heteroalkoxy groups, C₆-C₃₀ aryl groups, C₆-C₃₀ arylalkyl groups, C₆-C₃₀ aryloxy groups, C₂-C₃₀ heteroaryl groups, C₂-C₃₀ heteroarylalkyl groups, C₂-C₃₀ heteroaryloxy groups, C₅-C₃₀ cycloalkyl groups, C₂-C₃₀ heterocycloalkyl groups, C₁-C₃₀ alkylester groups, C₁-C₃₀ heteroalkylester groups, C₆-C₃₀ arylester groups, and C₂-C₃₀ heteroarylester groups, wherein at least one hydrogen bound to carbon of each R₁ and R₂ functional group is optionally substituted with another functional group;
R₃ to R₁₂ are each independently selected from the group consisting C₁-C₃₀ alkyl groups, C₁-C₃₀ heteroalkyl groups, C₁-C₃₀ alkoxy groups, C₁-C₃₀ heteroalkoxy groups, C₆-C₃₀ aryl groups, C₆-C₃₀ arylalkyl groups, C₆-C₃₀ aryloxy groups, C₂-C₃₀ heteroaryl groups, C₂-C₃₀ heteroarylalkyl groups, C₂-C₃₀ heteroaryloxy groups, C₅-C₃₀ cycloalkyl groups, C₂-C₃₀ heterocycloalkyl groups, C₁-C₃₀ alkylester groups, C₁-C₃₀ heteroalkylester groups, C₆-C₃₀ arylester groups, and C₂-C₃₀ heteroarylester groups, wherein at least one hydrogen bound to carbon of each R₃ to R₁₂ functional group is optionally substituted with another functional group;
X⁻ is an anion group wherein X is a molecule or atom that can be stabilized in an anion state and X is selected from F, Cl, Br, I, BF₄, PF₆ and (CₙF₂ₙ₊₁SO₂)₂N, wherein n is an integer from 1 to 50; and
Y is a NH group or a heteroatom selected from N, O, P and S being bonded to a C₁-C₂₀ alkyl group or a C₆-C₂₀ aryl group.

13. A conductive polymer composition film for an organic optoelectronic device comprising:
a conductive polymer comprising one or more monomers selected from the group consisting of polyaniline represented by the following Formula 6 and derivatives thereof; and pyrrole or thiophene represented by the following Formula 7 and derivatives thereof, 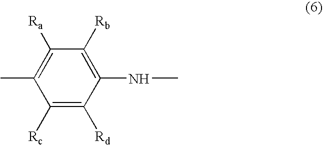
wherein Rₐ, R_{b}, R_{c} and R_{d} are each independently selected from the group consisting of hydrogen, C₁-C₃₀ alkyl groups, C₁-C₃₀ heteroalkyl groups, C₁-C₃₀ alkoxy groups, C₁-C₃₀ heteroalkoxy groups, C₆-C₃₀ aryl groups, C₆-C₃₀ arylalkyl groups, C₆-C₃₀ aryloxy groups, C₆-C₃₀ arylamine groups, C₆-C₃₀ pyrrole groups, C₆-C₃₀ thiophene groups, C₂-C₃₀ heteroaryl groups, C₂-C₃₀ heteroarylalkyl groups, C₂-C₃₀ heteroaryloxy groups, C₅-C₃₀ cycloalkyl groups, C₂-C₃₀ heterocycloalkyl groups, C₁-C₃₀ alkylester groups, C₁-C₃₀ heteroalkylester groups, C₆-C₃₀ arylester groups and C₂-C₃₀ heteroarylester groups, wherein at least one hydrogen bonded to carbon contained in Rₐ, R_{b}, R_{c} and R_{d} is optionally substituted with another functional group; 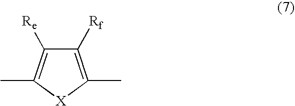
wherein X is a NH group or a heteroatom selected from N, O, P and S being bonded to a C₁-C₂₀ alkyl group or a C₆-C₂₀ aryl group;
Rₑ and R_{f} are each independently selected from the group consisting of a NH group, a heteroatom selected from N, O, P and S being bonded to a C₁-C₂₀ alkyl group or a C₆-C₂₀ aryl group, C₁-C₃₀ alkyl groups, C₆-C₃₀ aryl groups, C₁-C₃₀ alkoxy groups, C₁-C₃₀ heteroalkyl groups, C₁-C₃₀ heteroalkoxy groups, C₆-C₃₀ arylalkyl groups, C₆-C₃₀ aryloxy groups, C₆-C₃₀ arylamine groups, C₆-C₃₀ pyrrole groups, C₆-C₃₀ thiophene groups, C₂-C₃₀ heteroaryl groups, C₂-C₃₀ heteroarylalkyl groups, C₂-C₃₀ heteroaryloxy groups, C₅-C₃₀ cycloalkyl groups, C₂-C₃₀ heterocycloalkyl groups, C₁-C₃₀ alkylester groups, C₁-C₃₀ heteroalkylester groups, C₆-C₃₀ arylester groups and C₂-C₃₀ heteroarylester groups, wherein at least one hydrogen bonded to carbon contained in Rₑ and R_{f} is optionally substituted with another functional group; and
about 0.05 to about 50 parts by weight based on 100 parts by weight of said conductive polymer of at least one organic ionic salt selected from compounds represented by Formulae 2 to 5 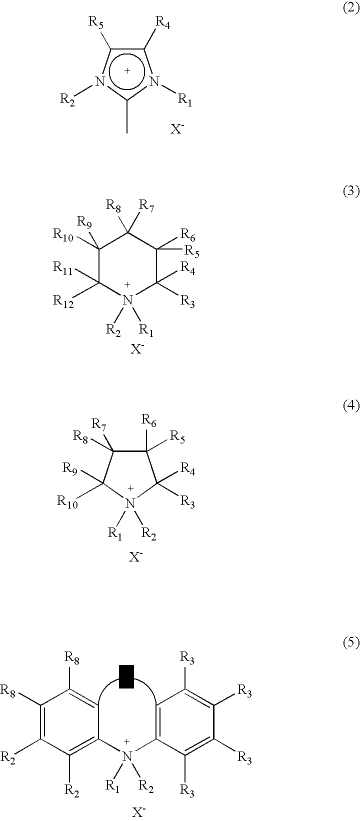
wherein R₁ and R₂ are each independently selected from the group consisting C₁-C₃₀ alkyl groups, C₁-C₃₀ heteroalkyl groups, C₁-C₃₀ alkoxy groups, C₁-C₃₀ heteroalkoxy groups, C₆-C₃₀ aryl groups, C₆-C₃₀ arylalkyl groups, C₆-C₃₀ aryloxy groups, C₂-C₃₀ heteroaryl groups, C₂-C₃₀ heteroarylalkyl groups, C₂-C₃₀ heteroaryloxy groups, C₅-C₃₀ cycloalkyl groups, C₂-C₃₀ heterocycloalkyl groups, C₁-C₃₀ alkylester groups, C₁-C₃₀ heteroalkylester groups, C₆-C₃₀ arylester groups, and C₂-C₃₀ heteroarylester groups, wherein at least one hydrogen bound to carbon of each R₁ and R₂ functional group is optionally substituted with another functional group;
R₃ to R₁₂ are each independently selected from the group consisting C₁-C₃₀ alkyl groups, C₁-C₃₀ heteroalkyl groups, C₁-C₃₀ alkoxy groups, C₁-C₃₀ heteroalkoxy groups, C₆-C₃₀ aryl groups, C₆-C₃₀ arylalkyl groups, C₆-C₃₀ aryloxy groups, C₂-C₃₀ heteroaryl groups, C₂-C₃₀ heteroarylalkyl groups, C₂-C₃₀ heteroaryloxy groups, C₅-C₃₀ cycloalkyl groups, C₂-C₃₀ heterocycloalkyl groups, C₁-C₃₀ alkylester groups, C₁-C₃₀ heteroalkylester groups, C₆-C₃₀ arylester groups, and C₂-C₃₀ heteroarylester groups, wherein at least one hydrogen bound to carbon of each R₃ to R₁₂ functional group is optionally substituted with another functional group;
X⁻ is an anion group wherein X is a molecule or atom that can be stabilized in an anion state and X is selected from F, Cl, Br, I, BF₄, PF₆ and (CₙF₂ₙ₊₁SO₂)₂N, wherein n is an integer from 1 to 50; and
Y is a NH group or a heteroatom selected from N, O, P and S being bonded to a C₁-C₂₀ alkyl group or a C₆-C₂₀ aryl group.

14. An organic optoelectronic device comprising the conductive polymer composition film according to claim 12.

15. An organic optoelectronic device comprising the conductive polymer composition film according to claim 13.
